(19) United States
(12) Patent Application Publication
(10) Pub. No.: US 2025/0390623 A1
(43) Pub. Date: Dec. 25, 2025

(54) IOT LARGE MODEL SYSTEMS AND METHODS FOR MONITORING SMART CITY BUILDING DEFORMATION

(71) Applicant: CHENGDU QINCHUAN IOT TECHNOLOGY CO., LTD., Chengdu (CN)

(72) Inventors: Hanshu SHAO, Chengdu (CN); Junyan ZHOU, Chengdu (CN); Guobin LUO, Chengdu (CN)

(73) Assignee: CHENGDU QINCHUAN IOT TECHNOLOGY CO., LTD., Chengdu (CN)

(21) Appl. No.: 19/315,473

(22) Filed: Aug. 29, 2025

(30) Foreign Application Priority Data
Aug. 5, 2025 (CN) 202511088695.8

(51) Int. Cl. G06F 30/13

(52) U.S. Cl. CPC G06F 30/13

(57) ABSTRACT

The present disclosure relates to an IoT large model system and a method for monitoring smart city building deformation. The method includes: determining a device distribution parameter based on three-dimensional data of a target building; generating a deployment instruction based on the device distribution parameter, and controlling a robot to install a plurality of monitoring devices based on the deployment instruction; determining, based on monitoring data obtained from the plurality of monitoring devices during a first time period, deformation data of the target building during a second time period using a deformation prediction model; determining a plurality of control forces based on the deformation data, and determining a first protection parameter based on the plurality of control forces; and sending a control signal to a damper network based on the first protection parameter to actuate a servo-motor actuator of each damper unit of the damper network to generate a force.

### CROSS-REFERENCE TO RELATED APPLICATIONS

This application claims priority to Chinese application No. 202511088695.8 filed on Aug. 5, 2025, the entire contents of which are incorporated herein by reference.

### TECHNICAL FIELD

The present disclosure relates to the technical field of building monitoring, and in particular relates to an Internet of Things (IoT) large model system and a method for monitoring smart city building deformation.

### BACKGROUND

In recent years, with the acceleration of the urbanization process, the safety and stability of buildings have attracted increasing attention. During the service life of buildings, buildings may undergo deformation due to natural factors (e.g., earthquakes, heavy rainfall) or human-induced factors (e.g., construction vibration, load changes, etc.), which in severe cases can even lead to structural failure. Current building monitoring technologies typically rely on manually installed observation points at limited critical locations, making it difficult to comprehensively reflect the deformation conditions across all areas of a building. Notably, unmonitored zones may exhibit deformation that goes undetected. Additionally, when a building deforms, existing systems cannot promptly assess risk loss based on the deformation data and activate corresponding emergency measures.

Therefore, to address these limitations in current monitoring techniques, it is hoped to provide an Internet of Things (IoT) large model system and a method for monitoring smart city building deformation to realize the comprehensive and real-time monitoring of the building, and to improve the effectiveness and timeliness of building safety management.

### SUMMARY

One or more embodiments of the present disclosure provide an Internet of Things (IoT) large model system for monitoring smart city building deformation. The IoT large model system comprises a governmental supervision management platform, a governmental supervision sensing network platform, and a governmental supervision perception control platform. The governmental supervision perception control platform includes a plurality of monitoring devices. The governmental supervision management platform is configured to: determine a device distribution parameter based on three-dimensional data of a target building; generate a deployment instruction based on the device distribution parameter, and control a robot to install the plurality of monitoring devices based on the deployment instruction; determine, based on monitoring data obtained from the plurality of monitoring devices during a first time period, deformation data of the target building during a second time period using a deformation prediction model, the deformation prediction model being a machine learning model, the deformation data including a deformation amplitude, a deformation location, and a deformation direction; determine a plurality of control forces based on the deformation data, and determine a first protection parameter based on the plurality of control forces; and send a control signal to a damper network based on the first protection parameter to actuate a servo-motor actuator of each damper unit of the damper network to generate a force.

One or more embodiments of the present disclosure provide a method for monitoring smart city building deformation. The method is executed based on a governmental supervision management platform of an Internet of Things (IoT) large model system for monitoring smart city building deformation. The method comprises: determining a device distribution parameter based on three-dimensional data of a target building; generating a deployment instruction based on the device distribution parameter, and controlling a robot to install a plurality of monitoring devices based on the deployment instruction; determining, based on monitoring data obtained from the plurality of monitoring devices during a first time period, deformation data of the target building during a second time period using a deformation prediction model, the deformation prediction model being a machine learning model, the deformation data including a deformation amplitude, a deformation location, and a deformation direction; determining a plurality of control forces based on the deformation data, and determining a first protection parameter based on the plurality of control forces; and sending a control signal to a damper network based on the first protection parameter to actuate a servo-motor actuator of each damper unit of the damper network to generate a force.

One or more embodiments of the present disclosure further provide a non-transitory computer-readable storage medium. The storage medium stores computer instructions. When a computer reads the computer instructions in the storage medium, the computer executes the method for monitoring smart city building deformation.

### BRIEF DESCRIPTION OF THE DRAWINGS

The present disclosure will be further illustrated by way of exemplary embodiments, which will be described in detail by means of the accompanying drawings. These embodiments are not limiting, and in these embodiments, the same numbering denotes the same structure.

FIG. 1 is an exemplary structural diagram of an Internet of Things (IOT) large model system for monitoring smart city building deformation according to some embodiments of the present disclosure.

FIG. 2 is an exemplary flowchart of a method for monitoring smart city building deformation according to some embodiments of the present disclosure.

FIG. 3 is an exemplary schematic diagram of a process for determining deformation data according to some embodiments of the present disclosure.

FIG. 4 is another exemplary flowchart of a method for monitoring smart city building deformation according to some embodiments of the present disclosure.

### DETAILED DESCRIPTION

In order to more clearly illustrate the technical solutions of the embodiments of the present disclosure, the accompanying drawings required to be used in the description of the embodiments will be briefly described below. Obviously, the accompanying drawings in the following description are only some examples or embodiments of the present disclosure, and it is possible for a person of ordinary skill in the art to apply the present disclosure to other similar scenarios in accordance with these drawings without creative labor. Unless obviously obtained from the context or the context illustrates otherwise, the same numeral in the drawings refers to the same structure or operation.

It should be understood that, as used herein, the terms “system”, “device”, “unit,” and/or “module” as used herein is a way to distinguish between different components, elements, parts, sections, or assemblies at different levels. However, these words may be replaced by other expressions if other expressions accomplish the same purpose.

As of the present disclosure and the claims, unless the context clearly suggests an exception, “a”, “an”, “the”, and/or “said” do not refer specifically to the singular, but may also include the plural. In general, the terms “includes” and “comprises” only suggest the inclusion of explicitly identified steps and elements that do not constitute an exclusive list, and the method or apparatus may also include other steps or elements.

Flowcharts are used in the present disclosure to illustrate operations performed by a system in accordance with embodiments of the present disclosure. It should be appreciated that the preceding or following operations are not necessarily performed in an exact sequence. Instead, steps can be processed in reverse order or simultaneously. Also, it is possible to add other operations to these processes, or to remove a step or steps from these processes.

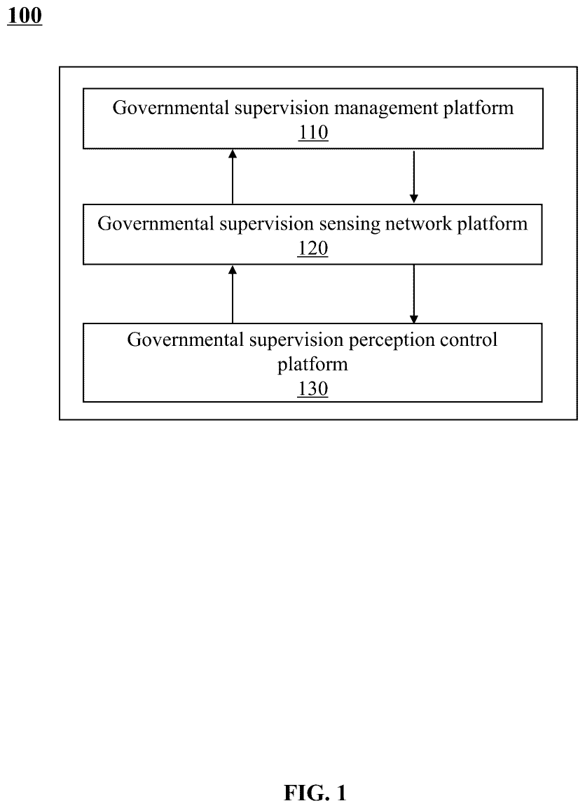

FIG. 1 is an exemplary structural diagram of an Internet of Things (IoT) large model system for monitoring smart city building deformation according to some embodiments of the present disclosure.

In some embodiments, as shown in FIG. 1, the Internet of Things (IoT) large model system for monitoring smart city building deformation (hereinafter referred to as the system) 100 may include a governmental supervision management platform 110, a governmental supervision sensing network platform 120, and a governmental supervision perception control platform 130.

Notably, the platforms are communicatively connected to each other, and the platforms may include respective processors and memories or may share the same processor and memory.

The governmental supervision management platform refers to a platform used by a government to regulate or manage information related to urban buildings. In some embodiments, the governmental supervision management platform is configured to: determine a device distribution parameter based on three-dimensional data of a target building; generate a deployment instruction based on the device distribution parameter, and control a robot to install the plurality of monitoring devices based on the deployment instruction; determine, based on monitoring data obtained from the plurality of monitoring devices during a first time period, deformation data of the target building during a second time period using a deformation prediction model; determine a plurality of control forces based on the deformation data, and determine a first protection parameter based on the plurality of control forces; and send a control signal to a damper network based on the first protection parameter to actuate a servo-motor actuator of each damper unit of the damper network to generate a force.

The governmental supervision sensing network platform refers to a platform used by a government to comprehensively manage sensing information. In some embodiments, the governmental supervision sensing network platform may interact with the governmental supervision management platform and the governmental supervision perception control platform.

The governmental supervision perception control platform refers to a platform used by a government to collect data and/or information. In some embodiments, the governmental supervision perception control platform includes a plurality of monitoring devices. The monitoring device refers to a device configured to monitor main factors that act directly on the target building to cause deformation to occur in the target building. For example, the monitoring device includes a light sensor, a rain gauge. In some embodiments, the governmental supervision perception control platform also includes dampers, drainage pumps, gas valves, or the like.

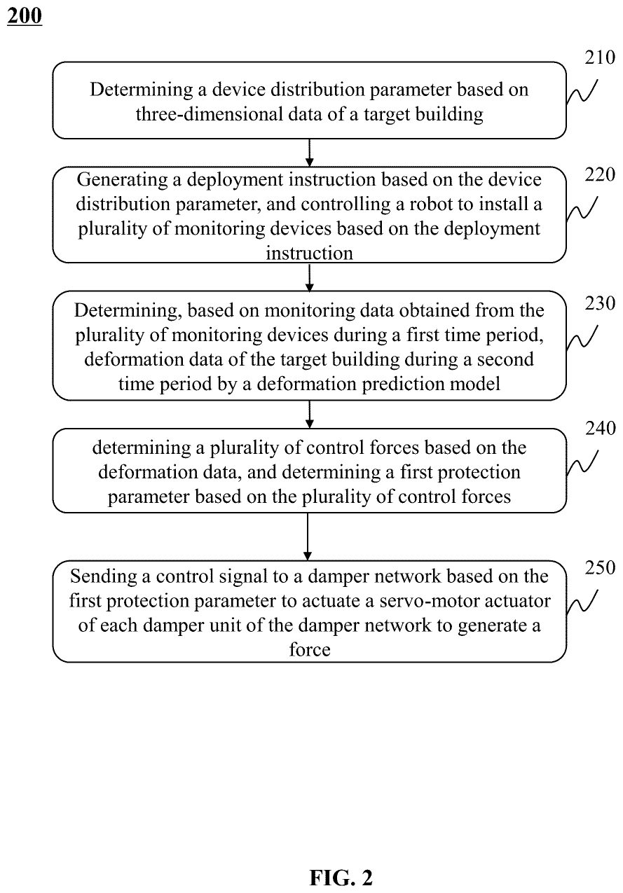

More descriptions of the Internet of Things (IoT) large model system for monitoring smart city building deformation may be found in FIGS. 2-4 and related descriptions thereof.

In some embodiments of the present disclosure, the use of the IoT large model system to supervise the city building can realize the monitoring of and rapid response to the deformation of the city building, and through intelligent analysis of the monitoring data to determine the deformation data of the city building and to carry out the intelligent protection, the hidden danger of safety is eliminated in time, therefore effectively improving the safety and reliability of urban buildings. At the same time, by integrating automated control and operations, it reduces manpower requirements and cuts management costs.

FIG. 2 is an exemplary flowchart of a method for monitoring smart city building deformation according to some embodiments of the present disclosure. As shown in FIG. 2, a process 200 includes step 210-step 250. In some embodiments, the process 200 may be executed by a governmental supervision management platform of an Internet of Things (IoT) large model system for monitoring smart city building deformation.
Step 210, determining a device distribution parameter based on three-dimensional data of a target building.

The target building refers to an object with a three-dimensional structure for monitoring deformation. For example, the target building includes a house (e.g., a residence, a factory) or a heritage building.

The three-dimensional (3D) data of the target building refers to data used to characterize a location and form (or 3D structure) of the target building in 3D space. In some embodiments, the three-dimensional data includes a three-dimensional model. In some embodiments, the three-dimensional data of the target building may be obtained from a third-party platform (e.g., a housing authority, a natural resource and planning agency), or the like.

The device distribution parameter refers to a parameter used to characterize installation locations of the plurality of monitoring devices. For example, the device distribution parameter may include a top of the target building, a floor of the target building, a sidewall of the target building, or a particular location. More descriptions of the monitoring device may be found in FIG. 1 and related descriptions thereof.

The governmental supervision management platform may determine the device distribution parameter in various ways based on the three-dimensional data of the target building. In some embodiments, the governmental supervision management platform may determine locations in the target building that satisfy a preset condition as the device distribution parameter based on the three-dimensional data of the target building. The preset condition may include the presence of hazards (e.g., missing building materials, minor cracks), time since last maintenance exceeding a preset time threshold, or the like. The preset time threshold may be preset manually.
Step 220, generating a deployment instruction based on the device distribution parameter, and controlling a robot to install a plurality of monitoring devices based on the deployment instruction.

The deployment instruction refers to an instruction or command for controlling the robot to install the plurality of monitoring devices. In some embodiments, the deployment instruction includes a movement path and a stopping location of the robot. The movement path refers to a path of the robot to move from a current location of the robot to an installation location of the monitoring device. The stopping location may be understood as a location where the robot installs a monitoring device, i.e., an installation location of the monitoring device. In some embodiments, the deployment instruction further includes installation steps of the monitoring device.

Understandably, device types of the plurality of monitoring devices may be the same or different, and the installation steps for monitoring devices of the same device type may be the same, but the installation locations for monitoring devices of the same device type may be different; and the installation steps for monitoring devices of different device types may be different, but the installation locations for monitoring devices of different device types may be the same or different (e.g., installing a plurality of different monitoring devices in the same location).

The governmental supervision management platform may generate the deployment instruction based on the device distribution parameter in various ways. In some embodiments, the governmental supervision management platform may generate the deployment instruction based on the device distribution parameter and the current location of the robot through a preset program. The preset program may be manually preset.

The robot may include an autonomous mobile robot. For example, the robot may complete the installation of the plurality of monitoring devices in accordance with the deployment instruction. In some embodiments, the governmental supervision management platform may be connected to the robot. In response to receiving the deployment instruction from the governmental supervision management platform, the robot may install the plurality of monitoring devices based on the deployment instruction.
Step 230, determining, based on monitoring data obtained from the plurality of monitoring devices during a first time period, deformation data of the target building during a second time period using a deformation prediction model.

The first time period refers to a certain time period that has already occurred. For example, the first time period includes a past week, a past month.

The monitoring data refers to relevant data obtained by the plurality of monitoring devices. In some embodiments, the monitoring data includes light time and rainfall. In some embodiments, the governmental supervision management platform may be communicatively connected to the plurality of monitoring devices to obtain the monitoring data during the first time period from the plurality of monitoring devices.

The second time period refers to a future time period. For example, the second time period includes a next week, a next month, or the like. Notably, a length of the second time period may be the same as or different from a length of the first time period.

The deformation data refers to data reflecting changes in structures, locations, shapes, etc., of the target building. In some embodiments, the deformation data includes a deformation amplitude, a deformation location, and a deformation direction. The deformation amplitude reflects a degree of deformation. For example, the deformation amplitude may include a displacement value, a strain value. The deformation location refers to a location where the target building deforms. For example, the deformation location may include a location where a crack develops in the target building. The deformation direction refers to a direction or an orientation in which the target building deforms. For example, the deformation direction may include a direction in which a beam of the target building is skewed.

The deformation prediction model refers to a model that predicts deformation data of the target building during the second time period. In some embodiments, the deformation prediction model is a machine learning model. For example, the deformation prediction model includes a Deep Neural Network (DNN) model, or other customized models, or the like, or any combination thereof.

In some embodiments, an input of the deformation prediction model may be monitoring data during the first time period, and an output of the deformation prediction model may be deformation data of the target building during the second time period.

In some embodiments, the deformation prediction model may be obtained by training an initial deformation prediction model with a plurality of first training samples with first labels. The first training sample may include sample monitoring data during a historical first time period. The sample monitoring data may include a sample light time and a sample rainfall. The first label may include deformation data of the target building actually detected during a historical second time period under the first training sample. The historical first time period precedes the historical second time period, the historical first time period has the same duration as the first time period, and the historical second time period has the same duration as the second time period.

In some embodiments, the first training sample and the first label may be obtained based on historical data.

In some embodiments, the governmental supervision management platform may input a plurality of first training samples with the first labels into the initial deformation prediction model, construct a loss function through the first labels and output results of the initial deformation prediction model, iteratively update parameters of the initial deformation prediction model based on the loss function through gradient descent or otherwise. When a preset training condition is satisfied, the model training is completed, and a trained deformation prediction model is obtained. The preset training condition may be that a loss function converges, a count of iterations reaches a threshold, or the like.

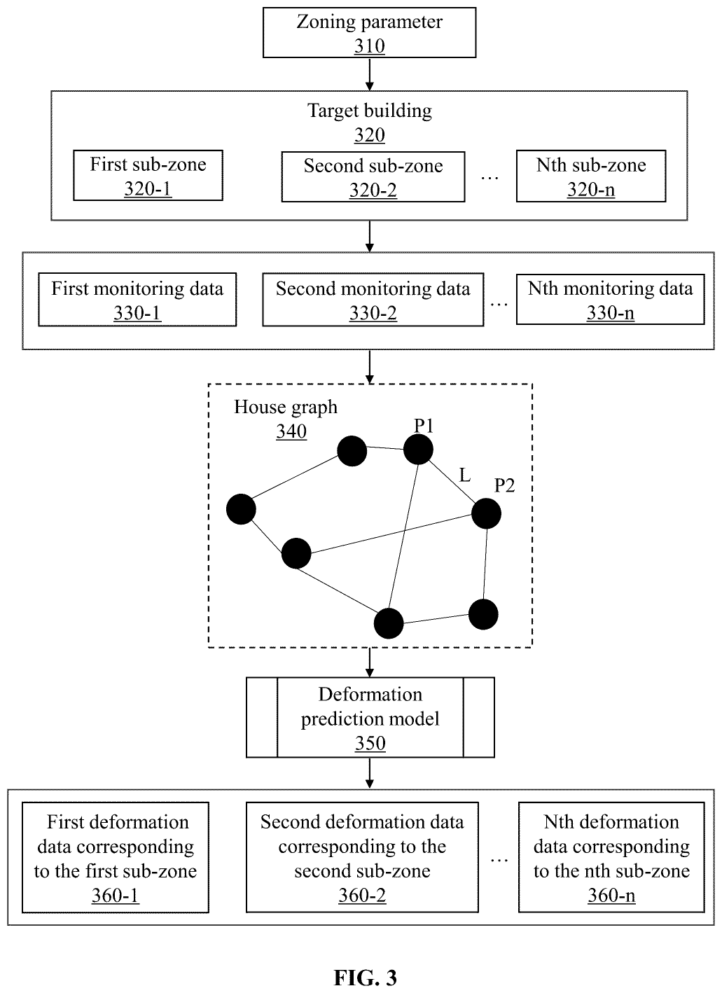

More descriptions of the step 230 may be found elsewhere in the present disclosure (e.g., FIG. 3 and related descriptions thereof).
Step 240, determining a plurality of control forces based on the deformation data, and determining a first protection parameter based on the plurality of control forces.

The control force refers to a force used to counteract the deformation data of the target building. For example, the control force may include torque, axial force, and shear force. In some embodiments, the control force may be realized by each damper unit of the damper network. For example, the servo-motor actuator of damper units may generate different forces to form the plurality of control forces by adjusting dampings of corresponding damper units. More descriptions of the damper network, the damper unit, and the servo-motor actuator may be found in step 250 and related descriptions thereof.

In some embodiments, for each damper unit of the damper network, the governmental supervision management platform may weight a plurality of deformation amplitudes (e.g., strain values) of a plurality of deformation locations within a preset distance range of the damper unit to generate a control urgency value; and in response to determining that the control urgency value is greater than a first preset threshold, the governmental supervision management platform may activate the damper network to intervene, performing step 250. The weights may be inversely proportional to a distance between the deformation location and the damper unit. The preset distance range and the first preset threshold may be manually preset.

The governmental supervision management platform may determine the plurality of control forces based on the deformation data in various ways. In some embodiments, the governmental supervision management platform may determine the plurality of control forces based on the deformation data by querying a first preset table. For example, the governmental supervision management platform may determine, based on the deformation location and the deformation direction in the deformation data, a type, a magnitude, etc., of a control force applied to the deformation location by querying the first preset table. The first preset table may include a plurality of correspondences between the plurality of control forces and the deformation data. In some embodiments, the first preset table may be constructed based on the deformation data through simulation. In other words, for a target building with a particular deformation data, a plurality of control forces for counteracting the particular deformation data may be obtained through the simulation.

The first protection parameter refers to a parameter for applying protection measures to the target building. In some embodiments, the first protection parameter may include a damping adjustment value. The damping adjustment value refers to an adjustment value applied to each damper unit of the damper network.

The governmental supervision management platform may determine the first protection parameter in various ways based on the plurality of control forces. In some embodiments, the governmental supervision management platform may determine the damping adjustment value by querying a second preset table. The second preset table may include a plurality of correspondence relationships between the plurality of control forces and a plurality of damping adjustment values. For example, the greater the control force, the greater a corresponding damping adjustment value of the control force. In some embodiments, the second preset table may be constructed based on the plurality of control forces through simulation.
Step 250, sending a control signal to a damper network based on the first protection parameter to actuate a servo-motor actuator of each damper unit of the damper network to generate a force.

The damper network refers to a network structure composed of a plurality of damper units working in coordination. The damper network may include a plurality of damper units pre-deployed at different locations within the target building. The damper network may enhance the anti-jamming capability of the target building by means of energy dissipation, vibration suppression, and dynamic regulation. For example, the damper network may dissipate vibration energy from earthquakes or strong winds and reduce the oscillation amplitude of the target building. As another example, the damper network may convert seismic wave energy into thermal energy and reduce deformation of the target building. As still another example, the damper network may exert a force on the target building to weaken or counteract the deformation of the target building. In some embodiments, the damper network is communicatively connected to the governmental supervision management platform.

Each damper unit may include a servo-motor actuator. In response to receiving a control signal, the servo-motor actuator may adjust the damping of the corresponding damper unit based on the first protection parameter to generate the force. The force is transmitted from the damper unit to an anchoring base connected to the damper unit, and ultimately acts on a main steel structure of the target building to generate a control force to counteract the deformation of the target building. The force refers to a force acting on the main steel structure of the target building. For example, the force may include an axial force, a shear force. The anchoring base may be pre-buried in the target building.

The control signal refers to a signal for coordinating and directing each damper unit of the damper network to perform specific operations. In some embodiments, the control signal may be used to drive the servo-motor actuator of the damper unit to adjust the damping of the damper unit based on the first protection parameter to generate the force.

In some embodiments, the governmental supervision management platform may automatically send the control signal to the damper network based on the first protection parameter. In response to receiving the control signal, the servo-motor actuators of damper units of the damper network may adjust the dampings of the corresponding damper units based on the first protection parameter (e.g., the damping adjustment value), to generate different forces to counteract deformations of the target building at different deformation locations.

In some embodiments of the present disclosure, by determining the plurality of control forces, and thereby determining the damping adjustment value of the damper unit, and by adjusting the damping of the damper unit to generate the force that is transmitted through the damper unit and the anchoring base to the main steel structure of the target building, a monitored deformation trend of the target building can be counteracted and the target building can be prevented from further turning into a dangerous building to protect the target building.

FIG. 3 is an exemplary schematic diagram of a method for determining deformation data according to some embodiments of the present disclosure.

In some embodiments, as shown in FIG. 3, the governmental supervision management platform may divide the target building 320 into a plurality of sub-zones (e.g., a first sub-zone 320-1, a second sub-zone 320-2, . . . , an Nth sub-zone 320-N) based on a zoning parameter 310; construct a house graph 340 based on monitoring data during a first time period within the plurality of sub-zones (e.g., first monitoring data 330-1 corresponding to the first sub-zone 320-1, second monitoring data 330-2 corresponding to the second sub-zone 320-2, . . . , and Nth monitoring data 330-N corresponding to the Nth sub-zone 320-N); and determine, based on the house graph 340, deformation data of the plurality of sub-zones of the target building 320 during a second time period (e.g., first deformation data 360-1 corresponding to the first sub-zone 320-1, second deformation data 360-2 corresponding to the second sub-zone 320-2, . . . , and Nth deformation data 360-N corresponding to the Nth sub-zone 320-N) by means of a deformation prediction model 350.

The zoning parameter refers to a relevant parameter used to partition the target building. For example, the zoning parameter may include a location where each sub-zone is located and a corresponding space size of each sub-zone. The sub-zones refer to a plurality of zones obtained by dividing the target building. As shown in FIG. 3, the target building 320 may be divided into N sub-zones, e.g., the first sub-zone 320-1, the second sub-zone 320-2, . . . , and the Nth sub-zone 320-N. N is an integer and not less than 2.

In some embodiments, the zoning parameter may be preset based on a priori experience.

In some embodiments, the governmental supervision management platform may obtain monitoring data during the first time period within the plurality of sub-zones via a monitoring device. More descriptions of the monitoring device, the first time period, and the monitoring data may be found in FIG. 2 and related descriptions thereof.

The house graph refers to a graph that reflects relevant information (e.g., three-dimensional data, monitoring data) about the target building. For example, the house graph may reflect information such as light times, rainfall, and other information that the target building receives.

In some embodiments, the governmental supervision management platform may construct the house graph through nodes and edges. Merely by way of example, as shown in FIG. 3, the house graph 340 includes a plurality of nodes and a plurality of edges. Two nodes of the plurality of nodes (e.g., P1 and P2) may be connected by an edge L.

The node refers to the target building and a partial zone within a preset range of the target building. For example, the node may include a sub-zone of the target building. As another example, the node may include a partial zone within a preset range of the target building (e.g., a zone covered by vegetation). The preset range may be manually preset. More descriptions of the preset range may be found in a later description.

In some embodiments, the plurality of nodes may include a first class node.

The first class node is the plurality of sub-zones. For example, one of the plurality of sub-zones may be called a first class node. In some embodiments, if there is a plurality of monitoring devices in one of the plurality of sub-zones, the governmental supervision management platform may further divide a coverage range (e.g., a spatial size) detectable by each of the plurality of monitoring devices within the sub-zone into a first class node. For example, a sub-zone having n (n being an integer not less than 2) monitoring devices may be further divided into n first class nodes.

In some embodiments, node characteristics of the first class node include monitoring data in the plurality of sub-zones during the first time period and the spatial sizes of the plurality of sub-zones. The spatial sizes of the plurality of sub-zones may be determined based on the zoning parameter. If there is no monitoring device within a certain first class node, the monitoring data in the node characteristics of the first class node is empty.

The edge refers to a boundary between neighboring sub-zones or between an environmental region and a neighboring sub-zone of the environmental region. For example, as shown in FIG. 3, there exists an edge L between two sub-zones (also called the first class node P). In some embodiments, a first class edge exists between the neighboring sub-zones.

The first class edge refers to a boundary that connects the neighboring sub-zones (which may also be called the first class node). The first class edge may be determined based on a location of the neighboring sub-zones.

In some embodiments, edge characteristics of the first class edge include a segmentation type of the neighboring sub-zones connected by the first class edge. The segmentation type refers to a manner used for region segmentation. For example, the segmentation type may include segmentation based on a building wall, segmentation based on the coverage range detectable by the monitoring device, no segmentation. In some embodiments, the segmentation type may be determined based on the three-dimensional data of the target building and the three-dimensional structure of the plurality of sub-zones.

In some embodiments, the node characteristics of the first class node further include a recent maintenance time and a corresponding maintenance type of the plurality of sub-zones, and a three-dimensional structure and a construction material of the plurality of sub-zones.

The recent maintenance time refers to a recent time when maintenance was performed on the target building. For example, a maintenance time may be a past week or a few days in the past.

The maintenance type refers to a type of maintenance performed on the target building. For example, the maintenance type may include wall patching, window and door repair, reinforcement, and renovation.

The three-dimensional structure of the sub-zone is used to characterize a shape and size of the sub-zone in three-dimensional space. In some embodiments, the three-dimensional structure of the sub-zone may be characterized by a three-dimensional model or may be characterized by data. For example, the sub-zone is a rectangular body, and the three-dimensional structure of the sub-zone may be characterized by numerical values of length, width, and height.

The construction material refers to information about a material used to construct the sub-zone (e.g., a type of material, an amount of material, etc.). For example, the construction material may include tiles, wood, concrete, or the like, and corresponding amounts thereof.

In some embodiments, the recent maintenance time and corresponding maintenance type of the plurality of sub-zones, the three-dimensional structure of the plurality of sub-zones, and the construction material may be obtained from a third-party platform (e.g., a housing authority, a natural resource and planning agency), or may be obtained by manual input.

In some embodiments, an environmental monitoring device is provided at an environmental monitoring point of an environmental region of the target building, and the environmental monitoring device is configured to obtain environmental data. The plurality of nodes further include a second class node for the environmental region within a preset range surrounding the target building, and node characteristics of the second class node include a covered type of the environmental region and the environmental data.

The environmental region refers to a type of environment within the preset range surrounding the target building. For example, the environmental region may include a vegetation-covered region, a concrete-covered region, a lake region, or the like. The environmental monitoring point refers to a location point used to monitor relevant information (e.g., the environmental data) about the environmental region. For example, the environmental monitoring point may include a monitoring location of the environmental monitoring device. The environmental monitoring device refers to a device that is configured to monitor the environmental data in the environmental region. For example, the environmental monitoring device may include, but is not limited to, a thermometer or a hygrometer, etc. The environmental data may reflect information related to a location of the environmental region. For example, the environmental data may include environmental temperature, environmental humidity.

The second class node refers to a portion area surrounding the target building within the preset range. In some embodiments, the second class node may include the environmental region within the preset range surrounding the target building.

In some embodiments, the preset range may include a range centered on the target building within a preset distance threshold (e.g., 5 m, 10 m, etc.) from the target building.

In some embodiments, the covered type of the environmental region of the node characteristics of the second class node may be obtained from the third-party platform (e.g., the natural resource and planning agency, a mapping app, etc.), or may be obtained by manual input.

In some embodiments, a second class edge connects the environmental region adjacent a plurality of sub-zones and the plurality of sub-zones, and edge characteristics of the second class edge include an environmental neighborhood factor.

The second class edge refers to a boundary between the environmental region adjacent to a sub-zone and the sub-zone. In some embodiments, the second class edge may be determined based on one of the plurality of sub-zones and an environmental region adjacent to the one of the plurality of sub-zones.

The environmental neighborhood factor refers to a parameter used to measure an impact of the environmental region on the target building. For example, if the environmental region has no impact on the target building, the environmental neighborhood factor is 0. As another example, the greater the impact of the environmental region on the target building, the greater the environmental neighborhood factor. In some embodiments, the environmental neighborhood factor may be determined empirically.

In some embodiments of the present disclosure, by dividing the target building and the environmental region within the preset range surrounding the target building into the plurality of nodes (the first class node and the second class node) and connecting the plurality of sub-zones and the environmental region with the second class edge, by monitoring the environmental data of the environmental region neighboring the plurality of sub-zones, and by taking into account the impact of the environmental region on the target building, the target building may be evaluated more comprehensively and carefully in order to protect the target building in a better manner.

In some embodiments, an input to the deformation prediction model may be the house graph, and an output of the deformation prediction model may be the deformation data of the plurality of sub-zones of the target building during the second time period.

In some embodiments, the deformation prediction model may also be obtained by training an initial deformation prediction model with a plurality of second training samples with second labels. In some embodiments, a second training sample may include a sample house graph, and a second label may include deformation data of the plurality of sub-zones of the sample target building actually detected during a historical second time period under the second training sample. The historical second time period is after a historical first time period. More descriptions of the historical first time period and the historical second time period may be found in FIG. 2 and related description thereof.

In some embodiments, the second training sample and the second label may be obtained based on historical data.

It is noted that the deformation prediction model (which may be referred to as a second deformation prediction model) and a training manner of the second deformation prediction model is similar to that of an aforementioned deformation prediction model (which may be referred to as a first deformation prediction model) and training manner of the first deformation prediction model may be found in step 230 in FIG. 2 and related descriptions thereof.

In some embodiments of the present disclosure, by dividing the target building into the plurality of sub-zones, constructing the house graph based on the deformation data within the plurality of sub-zones during the first time period, and further determining the deformation data of the plurality of sub-zones during the second time period based on the house graph, the determined deformation data of the target building during the second time period can be more accurate to better assess the deformation of the target building, to facilitate a subsequent adoption of more optimal protective measures to protect the target building.

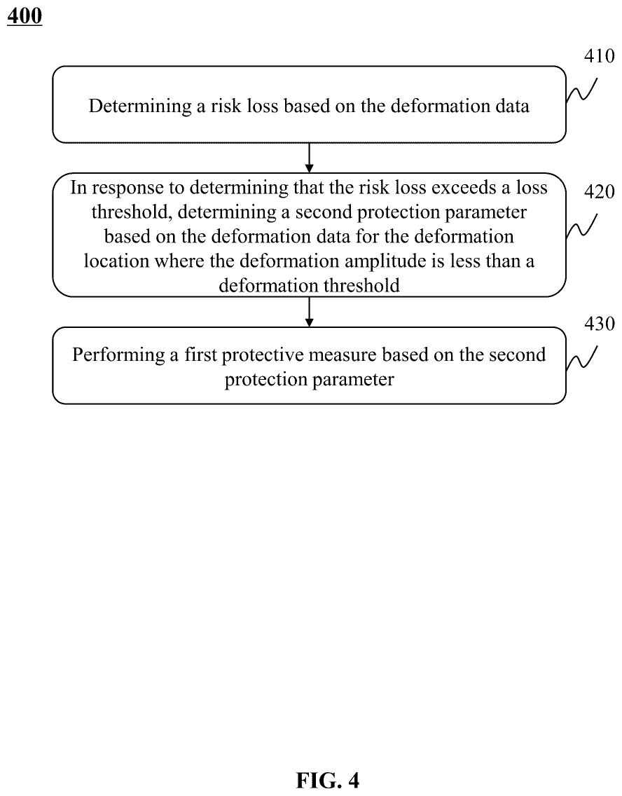

FIG. 4 is another exemplary flowchart of a method for monitoring smart city building deformation according to some embodiments of the present disclosure. As shown in FIG. 4, a process 400 includes step 410-step 430. In some embodiments, the process 400 may be performed by a governmental supervision management platform.
Step 410, determining a risk loss based on deformation data.

More descriptions of the deformation data may be found in step 230 in FIG. 2 and related descriptions thereof.

In some embodiments, the deformation data also includes a deformation type. The deformation type refers to a type of morphological change in a building. For example, the deformation type may include warping and bending caused by wet expansion and dry contraction, cracking and structural deformation triggered by thermal expansion and cold contraction, and localized corrosion caused by biological attack.

In some embodiments, the deformation type may be obtained in various ways. For example, the governmental supervision management platform may utilize surveillance cameras or drones, or the like, to periodically take images of the target building, and analyze the deformation of the target building in combination with an image processing technology to obtain the deformation type. As another example, the deformation type may be obtained by input after manual on-site inspection and monitoring.

The risk loss may be used to measure a danger degree of the deformation of the target building. For example, a larger value of the risk loss indicates a greater danger degree to the target building due to deformation.

In some embodiments, the governmental supervision management platform may determine, based on a deformation location and a deformation type, a deformation amplitude threshold to determine the risk loss by querying a third preset table. The third preset table may include a plurality of correspondences between the (deformation location and the deformation type) and the deformation amplitude threshold. For example, the smaller the corresponding deformation amplitude threshold for a deformation location and a deformation type, the deformation location and the deformation type have a greater impact on the deformation of the target building (e.g., a deformation location is a beam or other main structure, a deformation type is cracks and structural deformations triggered by thermal expansion and contraction). In some embodiments, the third preset table may be preset based on a priori experience.

The deformation amplitude threshold refers to a maximum allowable deformation value set for a deformation location and a deformation type of the target building. In some embodiments, the risk loss is negatively correlated to the deformation amplitude threshold. For example, the smaller the deformation amplitude threshold, the greater the risk loss.
Step 420, in response to determining that the risk loss exceeds a loss threshold, determining a second protection parameter based on the deformation data for the deformation location where the deformation amplitude is less than a deformation threshold.

The loss threshold refers to a maximum degree of loss that the target building can withstand. In some embodiments, the loss threshold may be obtained based on a priori experience.

The deformation threshold refers to a maximum value of the deformation of the target building that may be mitigated with the first protective measure. In some embodiments, the deformation threshold may be preset based on a priori experience. More descriptions of the first protective measure may be found in step 430 and related descriptions thereof.

The second protection parameter refers to a technical indicator and a device parameter set by the system to minimize damage to the target building triggered by external environmental factors. In some embodiments, the second protection parameter may include a gradient of a drainage system, an activated drainage pump, and a corresponding power.

The governmental supervision management platform may determine the second protection parameter based on the deformation data in various ways. In some embodiments, the governmental supervision management platform may determine the second protection parameter, based on the deformation data, by querying a fourth preset table. For example, when the deformation type is warping and buckling caused by wet expansion and dry contraction, the governmental supervision management platform may determine that there is a blistering (and possibly other liquids) behavior, and determine the gradient of the drainage system, the activated drainage pump, and the corresponding power, based on the deformation location, the deformation type, and the deformation amplitude, by querying the fourth preset table. The fourth preset table may be used to characterize a correspondence between the deformation data and the second protection parameter. In some embodiments, the fourth preset table may be determined based on a priori experience.
Step 430, performing a first protective measure based on the second protection parameter.

The first protective measure refers to a specific protective means for dynamically adjusting device operating parameters based on the second protection parameter. For example, the first protective measure may be enabling a drainage pump for de-pressurization of water drainage or activating a damper.

In some embodiments, the governmental supervision management platform may perform the first protective measure in various ways. For example, a gradient adjustment is performed based on the gradient of the drainage system in the second protection parameter utilizing an intelligent control algorithm.

In some embodiments, the governmental supervision management platform performs the first protective measure based on the second protection parameter includes: rotating a water pipe at a drainage outlet based on the gradient of the drainage system; and/or, controlling the activated drainage pump to operate based on the corresponding power.

For example, the governmental supervision management platform may perform the gradient adjustment of the drainage system by means of an adjustable joint, a gradient monitoring instrument, and a motorized adjustment device. For example, a gradient of the water pipe of a current drainage outlet is monitored by the gradient monitoring instrument, and if the gradient of the drainage outlet does not satisfy the gradient of the drainage system in the second protection parameter, the governmental supervision management platform will automatically send an adjustment signal to the motorized adjustment device of the adjustable joint, the motorized adjustment device will rotate the water pipe to a required gradient.

As another example, the governmental supervision management platform may monitor the operating parameters (e.g., a power) of the drainage pump in real time by an integrated drainage pump tester, and automatically send an adjustment signal to a drainage pump control system if the operating parameters of the drainage pump do not meet the power corresponding to the activated drainage pump in the second protection parameter. The drainage pump control system receives the adjustment signal and adjusts the operating parameters of the corresponding drainage pump to achieve the required power.

In some embodiments of the present disclosure, determining the risk loss through the deformation data and dynamically adjusting drainage system parameters (a drainage, a pump power) based on a dual determination of the risk loss and the deformation amplitude can achieve accurate risk response, improve structural safety while optimizing energy use efficiency; and avoiding excessive intervention in non-critical areas through a hierarchical protection mechanism can reduce a device loss, and improve an adaptive capability of the system under complex working conditions.

In some embodiments, the method for monitoring smart city building deformation further includes: in response to determining that the risk loss exceeds the loss threshold, determining a third protection parameter based on the deformation data for the deformation location where the deformation amplitude is greater than the deformation threshold, the third protection parameter including a gas shutdown instruction; and performing a second protective measure based on the third protection parameter, including: controlling a closing of a gas valve at a preset location based on the gas shutdown instruction.

More descriptions of the risk loss, the loss threshold, the deformation amplitude, and the deformation threshold may be found in FIG. 4 and related descriptions thereof.

The third protection parameter refers to an emergency parameter that is used to cut off a hazard source to minimize secondary damage if the risk loss exceeds the loss threshold and the deformation amplitude is greater than the deformation threshold. For example, the third protection parameter includes a whole-house power-off command, a water-off command. In some embodiments, the third protection parameter includes a gas shutdown instruction.

In some embodiments, in response to determining that the risk loss exceeds the loss threshold, for a deformation location where the deformation amplitude is greater than the deformation threshold, the governmental supervision management platform may automatically generate the third protection parameter by a preset program based on the deformation data. The preset program may be manually preset.

The second protective measure refers to a specific means of protection performed based on the third protection parameter. For example, the second protective measure includes turning off the main power switch, turning off the gas valve.

The gas shutdown instruction refers to a command used to control an interruption or shutdown of gas devices/valves. For example, the gas shutdown instruction may include a gas device requiring shutdown, a gas valve to be closed.

In some embodiments, the governmental supervision management platform may perform the second protective measure in various ways based on the third protection parameter. For example, the second protective measure includes threshold triggering, hierarchical decision, anomaly feedback, and other ways.

In some embodiments, the governmental supervision management platform may send the gas shutdown instruction to a gas valve at a preset location based on the gas shutdown instruction to control the gas valve at the preset location to close. The preset location may be determined manually. For example, the preset location may be a location where a gas valve is located in a sub-zone where a deformation location with a deformation amplitude greater than the deformation threshold occurs when the risk loss exceeds the loss threshold. For example, the gas valve may be a solenoid valve.

In some embodiments of the present disclosure, through the establishment of a dynamic prevention and control system for hierarchical risk, the system is able to accurately locate high-risk zones and automatically trigger shutdown action of the gas valve when the risk loss and structural deformation exceed the limit, to realize a transition from passive monitoring to active intervention. Additionally, a dual-condition triggering of the risk loss and the deformation amplitude avoids energy wastage or operational disruption due to false triggering, to enhance the accuracy of prevention and control.

It should be noted that the above descriptions of the process 200 and the process 400 are for the purpose of exemplification and illustration only, and do not limit the scope of application of the present disclosure. For a person skilled in the art, various modifications and changes may be made to the process 200 and the process 400 under the guidance of the present disclosure. However, these modifications and changes remain within the scope of the present disclosure.

Some embodiments of the present disclosure further provide a non-transitory computer-readable storage medium that stores computer instructions, and when a computer reads the computer instructions in the storage medium, the computer executes the aforementioned method for monitoring smart city building deformation.

The basic concepts have been described above, and it is apparent to those skilled in the art that the foregoing detailed disclosure serves only as an example and does not constitute a limitation of the present disclosure. While not expressly stated herein, various modifications, improvements, and amendments may be made to the present disclosure by those skilled in the art. Those types of modifications, improvements, and amendments are suggested in the present disclosure, so those types of modifications, improvements, and amendments remain within the spirit and scope of the exemplary embodiments of the present disclosure.

What is claimed is:

1. An Internet of Things (IoT) large model system for monitoring smart city building deformation, comprising a governmental supervision management platform, a governmental supervision sensing network platform, and a governmental supervision perception control platform; the governmental supervision perception control platform including a plurality of monitoring devices, wherein the governmental supervision management platform is configured to:
determine a device distribution parameter based on three-dimensional data of a target building;
generate a deployment instruction based on the device distribution parameter, and control a robot to install the plurality of monitoring devices based on the deployment instruction;
determine, based on monitoring data obtained from the plurality of monitoring devices during a first time period, deformation data of the target building during a second time period using a deformation prediction model, the deformation prediction model being a machine learning model, the deformation data including a deformation amplitude, a deformation location, and a deformation direction;
determine a plurality of control forces based on the deformation data, and determine a first protection parameter based on the plurality of control forces; and
send a control signal to a damper network based on the first protection parameter to actuate a servo-motor actuator of each damper unit of the damper network to generate a force.

2. The IoT large model system according to claim 1, wherein the governmental supervision management platform is further configured to:
divide the target building into a plurality of sub-zones based on a zoning parameter;
construct a house graph based on the monitoring data in the plurality of sub-zones during the first time period; and
determine, based on the house graph, the deformation data of the plurality of sub-zones of the target building within the second time period using the deformation prediction model.

3. The IoT large model system according to claim 2, wherein the house graph includes a plurality of nodes and a plurality of edges, the plurality of nodes include a first class node, the first class node is the plurality of sub-zones, and a first class edge connects neighboring sub-zones; node characteristics of the first class node include the monitoring data in the plurality of sub-zones during the first time period and spatial sizes of the plurality of sub-zones, and edge characteristics of the first class edge include a segmentation type of the neighboring sub-zones connected by the first class edge.

4. The IoT large model system according to claim 3, wherein the node characteristics of the first class node further include a recent maintenance time and a corresponding maintenance type of the plurality of sub-zones, and a three-dimensional structure and a construction material of the plurality of sub-zones.

5. The IoT large model system according to claim 3, wherein an environmental monitoring device is provided at an environmental monitoring point of an environmental region of the target building, and the environmental monitoring device is configured to obtain environmental data;
the plurality of nodes further include a second class node of the environmental region within a preset range surrounding the target building, and node characteristics of the second class node include a covered type of the environmental region and the environmental data; and
a second class edge connects the environmental region adjacent the plurality of sub-zones and the plurality of sub-zones, and edge characteristics of the second class edge include an environmental neighborhood factor.

6. The IoT large model system according to claim 1, wherein the deformation data further includes a deformation type;
the governmental supervision management platform is further configured to:
determine a risk loss based on the deformation data;
in response to determining that the risk loss exceeds a loss threshold, determine a second protection parameter based on the deformation data for the deformation location where the deformation amplitude is less than a deformation threshold, the second protection parameter including a gradient of a drainage system, an activated drainage pump and a corresponding power; and
perform a first protective measure based on the second protection parameter.

7. The IoT large model system according to claim 6, wherein the governmental supervision management platform is further configured to:
rotate a water pipe at a drainage outlet based on the gradient of the drainage system; and/or,
control the activated drainage pump to operate based on the corresponding power.

8. The IoT large model system according to claim 6, wherein the governmental supervision management platform is further configured to:
in response to determining that the risk loss exceeds the loss threshold, determine a third protection parameter based on the deformation data for the deformation location where the deformation amplitude is greater than the deformation threshold, the third protection parameter including a gas shutdown instruction; and
perform a second protective measure based on the third protection parameter.

9. The IoT large model system according to claim 8, wherein the governmental supervision management platform is configured to:
control a closing of a gas valve at a preset location based on the gas shutdown instruction.

10. A method for monitoring smart city building deformation, wherein the method is executed based on a governmental supervision management platform of an Internet of Things (IoT) large model system for monitoring smart city building deformation, the method comprising:
determining a device distribution parameter based on three-dimensional data of a target building;
generating a deployment instruction based on the device distribution parameter, and controlling a robot to install a plurality of monitoring devices based on the deployment instruction;
determining, based on monitoring data obtained from the plurality of monitoring devices during a first time period, deformation data of the target building during a second time period using a deformation prediction model, the deformation prediction model being a machine learning model, the deformation data including a deformation amplitude, a deformation location, and a deformation direction;
determining a plurality of control forces based on the deformation data, and determining a first protection parameter based on the plurality of control forces; and
sending a control signal to a damper network based on the first protection parameter to actuate a servo-motor actuator of each damper unit of the damper network to generate a force.

11. The method according to claim 10, wherein the determining, based on monitoring data obtained from the plurality of monitoring devices during a first time period, deformation data of the target building during a second time period using a deformation prediction model includes:
dividing the target building into a plurality of sub-zones based on a zoning parameter;
constructing a house graph based on the monitoring data in the plurality of sub-zones during the first time period; and
determining, based on the house graph, the deformation data of the plurality of sub-zones of the target building within the second time period by the deformation prediction model.

12. The method according to claim 11, wherein the house graph includes a plurality of nodes and a plurality of edges, the plurality of nodes include a first class node, the first class node is the plurality of sub-zones, and a first class edge connects neighboring sub-zones; node characteristics of the first class node include the monitoring data in the plurality of sub-zones during the first time period and spatial sizes of the plurality of sub-zones, and edge characteristics of the first class edge include a segmentation type of the neighboring sub-zones connected by the first class edge.

13. The method according to claim 12, wherein the node characteristics of the first class node further include a recent maintenance time and a corresponding maintenance type of the plurality of sub-zones, and a three-dimensional structure and a construction material of the plurality of sub-zones.

14. The method according to claim 12, wherein an environmental monitoring device is provided at an environmental monitoring point of an environmental region of the target building, and the environmental monitoring device is configured to obtain environmental data;
the plurality of nodes further include a second class node of the environmental region within a preset range surrounding the target building, and node characteristics of the second class node include a covered type of the environmental region and the environmental data; and
a second class edge connects the environmental region adjacent the plurality of sub-zones and the plurality of sub-zones, and edge characteristics of the second class edge include an environmental neighborhood factor.

15. The method according to claim 10, wherein the deformation data further includes a deformation type; and
the method further comprises:
determining a risk loss based on the deformation data;
in response to determining that the risk loss exceeds a loss threshold, determining a second protection parameter based on the deformation data for the deformation location where the deformation amplitude is less than a deformation threshold, the second protection parameter including a gradient of a drainage system, an activated drainage pump and a corresponding power; and
performing a first protective measure based on the second protection parameter.

16. The method according to claim 15, wherein the performing a first protective measure based on the second protection parameter includes:
rotating a water pipe at a drainage outlet based on the gradient of the drainage system; and/or
controlling the activated drainage pump to operate based on the corresponding power.

17. The method according to claim 15, wherein the method further comprises:
in response to determining that the risk loss exceeds the loss threshold, determining a third protection parameter based on the deformation data for the deformation location where the deformation amplitude is greater than the deformation threshold, the third protection parameter including a gas shutdown instruction; and
performing a second protective measure based on the third protection parameter.

18. The method according to claim 17, wherein the performing a second protective measure based on the third protection parameter includes:
controlling a closing of a gas valve at a preset location based on the gas shutdown instruction.

19. A non-transitory computer-readable storage medium, wherein the storage medium stores computer instructions, and when a computer reads the computer instructions in the storage medium, the computer executes the method for monitoring smart city building deformation of claim 10.
